(19) United States
(12) Patent Application Publication
(10) Pub. No.: US 2024/0321593 A1
(43) Pub. Date: Sep. 26, 2024

(54) DIELECTRIC BRIDGE FOR HIGH BANDWIDTH INTER-DIE COMMUNICATION

(71) Applicant: INTERNATIONAL BUSINESS MACHINES CORPORATION, Armonk, NY (US)

(72) Inventors: Mukta Ghate Farooq, Hopewell Junction, NY (US); Aakrati Jain, Albany, NY (US)

(21) Appl. No.: 18/123,402

(22) Filed: Mar. 20, 2023

(51) Int. Cl. H01L 21/48; H01L 21/762; H01L 23/00; H01L 23/538; H01L 25/00; H01L 25/16

(52) U.S. Cl. CPC H01L 21/486; H01L 21/4853; H01L 21/76224; H01L 23/5384; H01L 24/16; H01L 25/16; H01L 25/50; H01L 2224/16145; H01L 2924/1431; H01L 2924/1434; H01L 2924/15311

(57) ABSTRACT

A microelectronic package is provided. The microelectronic package includes a substrate. The microelectronic package includes a first die and a second die that are attached to the substrate. Also, the microelectronic package includes a dielectric structure that includes at least one electrical wiring. The at least one electrical wiring that is included in the dielectric structure electrically connects the first die to the second die.

### BACKGROUND

The present disclosure relates generally to fabrication methods and resulting structures for semiconductor devices and, in particular, to microelectronic packages and bridges for high bandwidth inter-die communication and methods of manufacturing such bridges.

In general, a bridge is a structure that allows for a communicative electrical connection between different electronic dies. One example of a bridge is a silicon bridge that is a small piece of silicon that may include back-end-of-line (BEOL) layers or films on a back side thereof. A silicon bridge enables a connection to be made between two physically separate dies (e.g., a first die may be a memory die and a second die may be a logic die). In certain examples, the silicon bridge is in the form of a chip that is embedded into or on top of a packaging substrate upon which the dies are mounted, and electrical connection wires for communicating between the different dies are embedded into the silicon bridge chip. When using a silicon bridge, there may be a complex fabrication process, the inter-die connection pathways may have longer travel distances, a higher energy requirement (e.g., pJ/bit) for the communication, a lower latency, and/or a lower bandwidth. Thus, there may be a need for alternative bridge structures that lessen or eliminate some of these effects.

### SUMMARY

Embodiments of the present disclosure relate to a microelectronic package comprising: a substrate; a first die and a second die attached to the substrate; and a dielectric structure including at least one electrical wiring that electrically connects the first die to the second die. In these embodiments, a simplified assembly process is achieved as compared to, for example, a silicon bridge on packaging substrate. This may allow for a higher yield than related package assembly techniques. Also, it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

In some embodiments, the dielectric structure connecting the first die and the second die is between the first and second dies and the substrate. This may allow for a simplified assembly process, and through silicon vias (TSVs) may not have to be formed in the chips, which may improve yield and reduce manufacturing costs. Also, the overall height of the microelectronic package may be reduced because the dielectric structure is on the same side of the chips as the solder features, which decreased the size of the overall structure.

In some embodiments of the microelectronic package, the first die and the second die are between the through-dielectric vias and the substrate. This orientation of the microelectronic package allows for deposition of a single set (or pitch, or size) of bumps, making the manufacturing process simpler. The mold compound also provides a higher structural support during handing and processing, as compared to a more fragile oxide layer in a case where the bridge is on the bottom.

In certain embodiments of the microelectronic package, the dielectric structure is positioned between the first and second dies and the lid. This orientation of the microelectronic package allows for deposition of a single set (or pitch, or size) of bumps, making the manufacturing process simpler. The mold compound also provides a higher structural support during handing and processing, as compared to a more fragile oxide layer in a case where the bridge is on the bottom.

In certain embodiments of the microelectronic package, at least one of the first die and the second die includes a through-chip via that connects to the at least one electrical wiring. This may allow for additional electrical connections between the electrical wiring and the laminate substrate.

In certain embodiments of the microelectronic package, a separation area between the first die and the second die is filled with a dielectric material. This enables the first die to be anchored to the second die, and also allows for the two dies to be separated by a non-conducting materials to prevent electrical shorting.

Embodiments of the present disclosure relate to a method of manufacturing a microelectronic package. The method includes attaching a first die and a second die attached to a substrate; and forming a dielectric structure including at least one electrical wiring that electrically connects the first die to the second die. In these embodiments, a simplified assembly process is achieved as compared to, for example, a silicon bridge on packaging substrate. This may allow for a higher yield than related package assembly techniques. Also, it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

In some embodiments of the method of manufacturing the microelectronic package, the dielectric structure connecting the first die and the second die is between the first and second dies and the substrate. This may allow for a simplified assembly process, and through silicon vias (TSVs) may not have to be formed in the chips, which may improve yield and reduce manufacturing costs. Also, the overall height of the microelectronic package may be reduced because the dielectric structure is on the same side of the chips as the solder features, which decreased the size of the overall structure.

In some embodiments of the method of manufacturing the microelectronic package, the first die and the second die are between the electrical wiring and the substrate. This configuration may allow for formation of through-mold vias, that allow for a heat transfer path between the dies and the lid.

In some embodiments of the method of manufacturing the microelectronic package, the dielectric structure is positioned between the first and second dies and the lid. This may allow for a simplified assembly process, and through silicon vias (TSVs) may not have to be formed in the chips, which may improve yield and reduce manufacturing costs. Also, the overall height of the microelectronic package may be reduced because the dielectric structure is on the same side of the chips as the solder features, which decreased the size of the overall structure.

In some embodiments of the method of manufacturing the microelectronic package, at least one of the first die and the second die includes a through-chip via that connects to the at least one through-dielectric via. This may allow for additional electrical connections between the through-dielectric vias and the laminate substrate.

In some embodiments of the method of manufacturing the microelectronic package, a separation area between the first die and the second die is filled with a dielectric material. This enables the first die to be anchored to the second die, and also allows for the two dies to be separated by a non-conducting material to prevent electrical shorting.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A shows a schematic cross-sectional diagram for a dielectric bridge structure for chip-to-chip connections at an intermediate stage of the manufacturing process, in accordance with embodiments.

FIG. 1B shows a schematic cross-sectional diagram for the dielectric bridge structure of FIG. 1A at a subsequent stage of the fabrication process, in accordance with embodiments.

FIG. 1C shows a schematic cross-sectional diagram for the dielectric bridge structure of FIG. 1B at a subsequent stage of the fabrication process, in accordance with embodiments.

FIG. 1D shows a schematic cross-sectional diagram for the dielectric bridge structure of FIG. 1C at a subsequent stage of the fabrication process, in accordance with embodiments.

FIG. 1E shows a schematic cross-sectional diagram for the dielectric bridge structure of FIG. 1D at a subsequent stage of the fabrication process, in accordance with embodiments.

FIG. 1F shows a schematic cross-sectional diagram for the dielectric bridge structure of FIG. 1E at a subsequent stage of the fabrication process, in accordance with embodiments.

FIG. 1G shows a schematic cross-sectional diagram for the dielectric bridge structure of FIG. 1F at a subsequent stage of the fabrication process, in accordance with embodiments.

FIG. 1H shows a schematic cross-sectional diagram for the dielectric bridge structure of FIG. 1G at a subsequent stage of the fabrication process, in accordance with embodiments.

FIG. 2A shows a schematic cross-sectional diagram for a dielectric bridge structure for chip-to-chip connections at an intermediate stage of the manufacturing process, in accordance with embodiments.

FIG. 2B shows a schematic cross-sectional diagram for the dielectric bridge structure of FIG. 2A at a subsequent stage of the fabrication process, in accordance with embodiments.

FIG. 2C shows a schematic cross-sectional diagram for the dielectric bridge structure of FIG. 2B at a subsequent stage of the fabrication process, in accordance with embodiments.

FIG. 2D shows a schematic cross-sectional diagram for the dielectric bridge structure of FIG. 2C at a subsequent stage of the fabrication process, in accordance with embodiments.

FIG. 2E shows a schematic cross-sectional diagram for the dielectric bridge structure of FIG. 2D at a subsequent stage of the fabrication process, in accordance with embodiments.

FIG. 2F shows a schematic cross-sectional diagram for the dielectric bridge structure of FIG. 2E at a subsequent stage of the fabrication process, in accordance with embodiments.

FIG. 2G shows a schematic cross-sectional diagram for the dielectric bridge structure of FIG. 2F at a subsequent stage of the fabrication process, in accordance with embodiments.

FIG. 2H shows a schematic cross-sectional diagram for the dielectric bridge structure of FIG. 2G at a subsequent stage of the fabrication process, in accordance with embodiments.

FIG. 2I shows a schematic cross-sectional diagram for the dielectric bridge structure of FIG. 2H at a subsequent stage of the fabrication process, in accordance with embodiments.

FIG. 3A shows a schematic cross-sectional diagram for a dielectric bridge structure for chip-to-chip connections at an intermediate stage of the manufacturing process, in accordance with embodiments.

FIG. 3B shows a schematic cross-sectional diagram for the dielectric bridge structure of FIG. 3A at a subsequent stage of the fabrication process, in accordance with embodiments.

FIG. 3C shows a schematic cross-sectional diagram for the dielectric bridge structure of FIG. 3B at a subsequent stage of the fabrication process, in accordance with embodiments.

FIG. 3D shows a schematic cross-sectional diagram for the dielectric bridge structure of FIG. 3C at a subsequent stage of the fabrication process, in accordance with embodiments.

FIG. 3E shows a schematic cross-sectional diagram for the dielectric bridge structure of FIG. 3D at a subsequent stage of the fabrication process, in accordance with embodiments.

FIG. 3F shows a schematic cross-sectional diagram for the dielectric bridge structure of FIG. 3E at a subsequent stage of the fabrication process, in accordance with embodiments.

FIG. 3G shows a schematic cross-sectional diagram for the dielectric bridge structure of FIG. 3F at a subsequent stage of the fabrication process, in accordance with embodiments.

FIG. 3H shows a schematic cross-sectional diagram for the dielectric bridge structure of FIG. 3G at a subsequent stage of the fabrication process, in accordance with embodiments.

FIG. 3I shows a schematic cross-sectional diagram for the dielectric bridge structure of FIG. 3H at a subsequent stage of the fabrication process, in accordance with embodiments.

FIG. 3J shows a schematic cross-sectional diagram for the dielectric bridge structure of FIG. 3I at a subsequent stage of the fabrication process, in accordance with embodiments.

FIG. 4A shows a schematic cross-sectional diagram for a dielectric bridge structure for chip-to-chip connections at an intermediate stage of the manufacturing process, in accordance with embodiments.

FIG. 4B shows a schematic cross-sectional diagram for the dielectric bridge structure of FIG. 4A at a subsequent stage of the fabrication process, in accordance with embodiments.

FIG. 4C shows a schematic cross-sectional diagram for the dielectric bridge structure of FIG. 4B at a subsequent stage of the fabrication process, in accordance with embodiments.

FIG. 4D shows a schematic cross-sectional diagram for the dielectric bridge structure of FIG. 4C at a subsequent stage of the fabrication process, in accordance with embodiments.

FIG. 4E shows a schematic cross-sectional diagram for the dielectric bridge structure of FIG. 4D at a subsequent stage of the fabrication process, in accordance with embodiments.

FIG. 4F shows a schematic cross-sectional diagram for the dielectric bridge structure of FIG. 4E at a subsequent stage of the fabrication process, in accordance with embodiments.

FIG. 4G shows a schematic cross-sectional diagram for the dielectric bridge structure of FIG. 4F at a subsequent stage of the fabrication process, in accordance with embodiments.

FIG. 4H shows a schematic cross-sectional diagram for the dielectric bridge structure of FIG. 4G at a subsequent stage of the fabrication process, in accordance with embodiments.

FIG. 5A shows a schematic cross-sectional diagram for a dielectric bridge structure for chip-to-chip connections at an intermediate stage of the manufacturing process, in accordance with embodiments.

FIG. 5B shows a schematic cross-sectional diagram for the dielectric bridge structure of FIG. 5A at a subsequent stage of the fabrication process, in accordance with embodiments.

FIG. 5C shows a schematic cross-sectional diagram for the dielectric bridge structure of FIG. 5B at a subsequent stage of the fabrication process, in accordance with embodiments.

FIG. 5D shows a schematic cross-sectional diagram for the dielectric bridge structure of FIG. 5C at a subsequent stage of the fabrication process, in accordance with embodiments.

FIG. 5E shows a schematic cross-sectional diagram for the dielectric bridge structure of FIG. 5D at a subsequent stage of the fabrication process, in accordance with embodiments.

FIG. 5F shows a schematic cross-sectional diagram for the dielectric bridge structure of FIG. 5E at a subsequent stage of the fabrication process, in accordance with embodiments.

FIG. 5G shows a schematic cross-sectional diagram for the dielectric bridge structure of FIG. 5F at a subsequent stage of the fabrication process, in accordance with embodiments.

FIG. 6A shows a schematic cross-sectional diagram for a dielectric bridge structure for chip-to-chip connections at an intermediate stage of the manufacturing process, in accordance with embodiments.

FIG. 6B shows a schematic cross-sectional diagram for the dielectric bridge structure of FIG. 6A at a subsequent stage of the fabrication process, in accordance with embodiments.

FIG. 6C shows a schematic cross-sectional diagram for the dielectric bridge structure of FIG. 6B at a subsequent stage of the fabrication process, in accordance with embodiments.

FIG. 6D shows a schematic cross-sectional diagram for the dielectric bridge structure of FIG. 6C at a subsequent stage of the fabrication process, in accordance with embodiments.

FIG. 6E shows a schematic cross-sectional diagram for the dielectric bridge structure of FIG. 6D at a subsequent stage of the fabrication process, in accordance with embodiments.

FIG. 7A shows a schematic cross-sectional diagram for a dielectric bridge structure for chip-to-chip connections at an intermediate stage of the manufacturing process, in accordance with embodiments.

FIG. 7B shows a schematic cross-sectional diagram for the dielectric bridge structure of FIG. 7A at a subsequent stage of the fabrication process, in accordance with embodiments.

FIG. 7C shows a schematic cross-sectional diagram for the dielectric bridge structure of FIG. 7B at a subsequent stage of the fabrication process, in accordance with embodiments.

FIG. 7D shows a schematic cross-sectional diagram for the dielectric bridge structure of FIG. 7C at a subsequent stage of the fabrication process, in accordance with embodiments.

### DETAILED DESCRIPTION

The present disclosure relates generally to fabrication methods and resulting structures for semiconductor devices and, in particular, to microelectronic packages and a dielectric bridge for high bandwidth inter-die communication and methods of manufacturing such semiconductor devices.

As mentioned above a silicon bridge is an example of a bridge structure that enables a connection to be made between two physically separate dies (e.g., a first die may be a memory die and a second die may be a logic die). In certain examples, the silicon bridge is in the form of a chip that is embedded into or on top of a packaging substrate upon which the dies are mounted, and electrical connection wires for communicating between the different dies are embedded into the silicon bridge chip. When using a silicon bridge, there may be a complex fabrication process, the inter-die connection pathways may have longer travel distances, a higher energy requirement (e.g., pJ/bit) for the communication, a lower latency, and/or a lower bandwidth.

However, the present embodiments provide a dielectric bridge structure that includes at least one conductor line that electrically connects a first die to a second die. The present embodiments may lessen one or more of the effects (i.e., a complex fabrication process, the inter-die connection pathways may have longer travel distances, a higher energy requirement (e.g., pJ/bit) for the communication, a lower latency, and/or a lower bandwidth) discussed above.

The flowcharts and cross-sectional diagrams in the Figures illustrate methods of manufacturing a microelectronic package according to various embodiments. In some alternative implementations, the manufacturing steps/operations may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

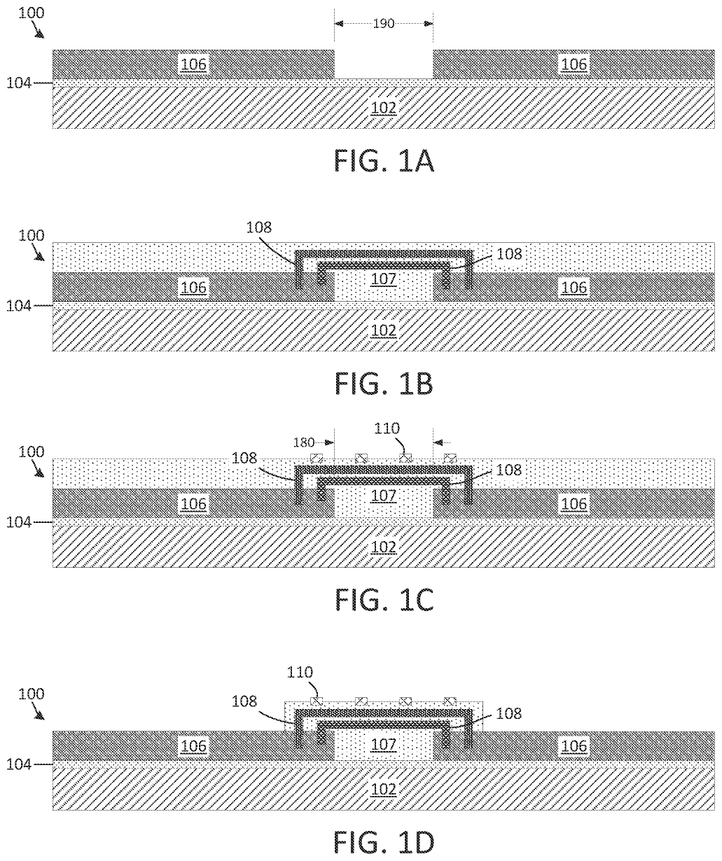

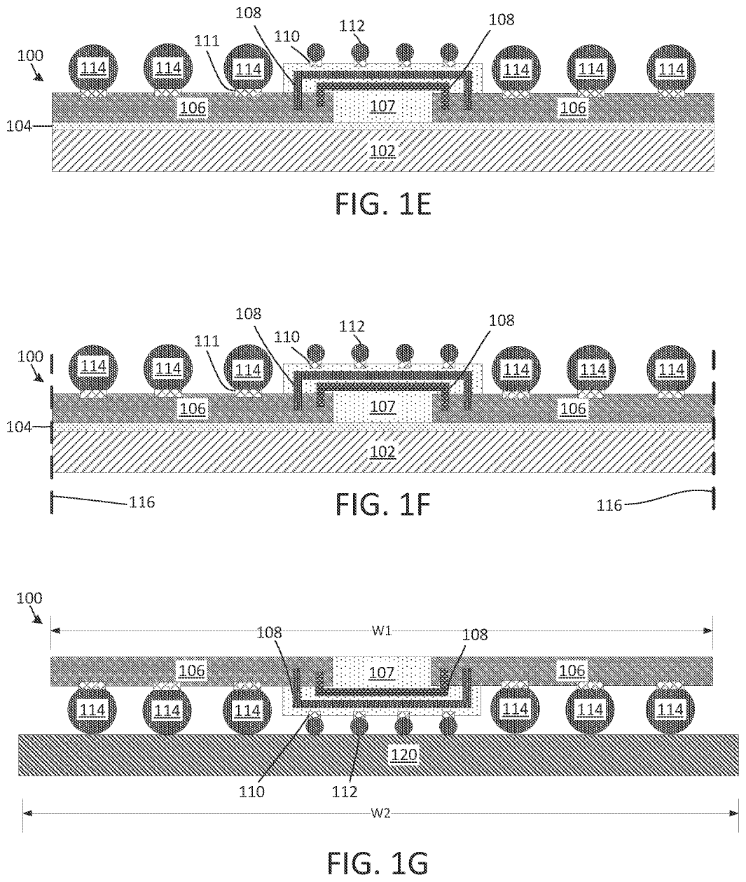

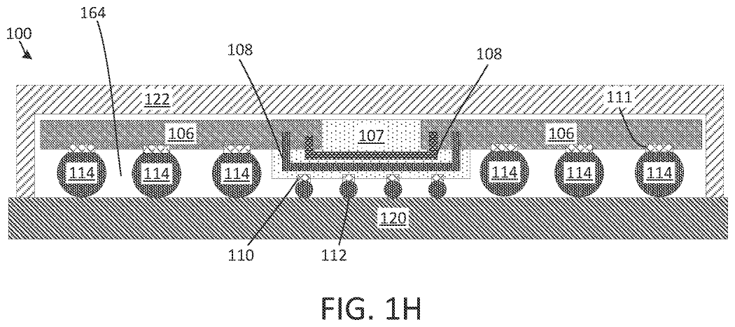

Referring now to the drawings in which like numerals represent the same or similar elements and initially to FIG. 1A, as shown in the multichip structure 100 of FIG. 1A, a substrate 102 is provided. The substrate 102 (or carrier wafer) as known in the art, or any other suitable material(s). In certain embodiments, an adhesive layer 104 is provided on the substrate 102. The adhesive layer 104 may be comprised on any suitable material(s) and allows for the different chips 106 to be mounted to the substrate 102. Two physically separate chips 106 are mounted on the substrate 102 with some distance therebetween. The chips 106 may be of the same type or different types (e.g., a first die may be a memory die and a second die may be a logic die). In certain examples, the chips 106 are separated from each other by about 10 μm or more to create a space (or a trench 180) therebetween. In certain examples, the chips 106 are reconstituted and thinned chips.

Referring now to FIG. 1B, this figure shows a schematic cross-sectional diagram for the multichip structure 100 of FIG. 1A at a subsequent stage of the fabrication process, in accordance with embodiments. As shown in FIG. 1B, a dielectric layer 107 is deposited over and between the chips 106. The dielectric layer 107 may be, for example, an oxide layer. In one example, the dielectric layer 107 comprises one or more of the following; SiO₂, SiN, SiCN, a polymer, an epoxy, or a suitable organic material. In an example, one or more organic oxide materials are used for the dielectric layer 107 that allow for low temperature (e.g., 175° C.) deposition. In certain examples, a height (or thickness) of the dielectric layer 107 above the upper surfaces of the chips 106 may be from 10-60 μm. This thickness of the dielectric layer 107 allows for conductor lines (discussed in further detail below) to be formed in the dielectric layer 107 to connect the chips 106.

As shown in FIG. 1B, through-dielectric vias 108 (or electrically conductive traces, or conductor lines, or metal lines) are formed in the dielectric layer 107 with any suitable combination of patterning, material deposition and material removal steps. For example, the through-dielectric vias 108 may be formed using standard Cu damascene back-end-of-line (BEOL) processing. In one example of forming the through-dielectric vias 108, after the dielectric layer 107 is formed, suitable patterning and material removal process (e.g., RIE etching) are used to form vertical through-holes that extend through the dielectric layer 107 and, in certain examples, down into a portion of the chips 106 to expose electrical contacts in the chips 106. Then, a material deposition process is performed to deposit a suitable metal material of the through-dielectric vias 108 in these vertical through-holes to fill up the holes. In one example, a material removal process such a CMP may be used to remove some of the overburden of the dielectric layer 107 and the vertical metal portions of the through-dielectric vias 108. Then, suitable material deposition and patterning processes are performed to form a first horizontal portion of the metal material that extends horizontally to electrically connect the two chips 106. Then, additional material of the dielectric layer 107 may be deposited over this first horizontal portion of the through-dielectric vias 108. An additional horizontal portion of the through-dielectric vias 108 may be deposited to connect additional vertical portions of the through-dielectric vias 108, followed by deposition of additional material of the dielectric layer 107. It should be appreciated that the arrangement and stacking of the various through-dielectric vias 108 is merely one example, and any suitable number or arrangement of metal connections can be made in the dielectric layer 107 by standard Cu damascene BEOL processing to produce the electrical connection structures of the through-dielectric vias and to connect the chips 106.

Referring now to FIG. 1C, this figure shows a schematic cross-sectional diagram for the multichip structure 100 of FIG. 1B at a subsequent stage of the fabrication process, in accordance with embodiments. As shown in FIG. 1C, metal contacts 110 (or pads, or under bump metal (UBM) layers) are formed on the dielectric layer 107 on or above the through-dielectric vias 108. The metal contacts 110 are formed in locations where solder bumps will be formed (discussed in detail below) at a later stage of the manufacturing process. As shown in FIG. 1C, the through-dielectric vias 108 and the dielectric layer 107 form electrical connections (e.g., BEOL wirings) between the two different chips 106.

Referring now to FIG. 1D, this figure shows a schematic cross-sectional diagram for the multichip structure 100 of FIG. 1C at a subsequent stage of the fabrication process, in accordance with embodiments. As shown in FIG. 1D, the dielectric layer 107 is initially deposited over the entire surfaced of the multichip structure 100, and then any suitable patterning and material removal processes may be used to remove portions of the dielectric layer 107 over the chips 106 (which maintain some overlap over the chips 106 to allow for formation of the wirings and the through-dielectric vias 108 that connect the chips 106 together. In an example, a ratio of the height (or thickness) of the dielectric layer 107 above the surface of the adhesive layer 104 to the distance between the chips 106 is about 1:1. However, it should be appreciated that other suitable ratios of the height to separation distance may be used. The through-dielectric vias 108 (or conductor lines) may be comprised of any suitable conductive material (e.g., copper).

Referring now to FIG. 1E, this figure shows a schematic cross-sectional diagram for the multichip structure 100 of FIG. 1D at a subsequent stage of the fabrication process, in accordance with embodiments. As shown in FIG. 1E, in an embodiments, a number of second metal contacts 111 (or pads, or under bump metal layers) are formed on the chips 106. These second metal contacts 111 may be comprised of the same or different materials than the metal contacts 110, and may be sized to be larger than the metal contacts 110 to be able to accept a larger solder feature than the metal contacts 110. A number of solder features 112 are formed on the metal contacts 110, and a number of second solder features 114 are formed on the second metal contacts 111. In an embodiment, the solder features 112 and the second solder features 114 are solder balls are part of a ball grid array (BGA). As shown, the solder features 112 and the second solder features 114 may permit the microchip structure 100 to be mounted and electrically coupled to, for example, an underlying printed circuit board (PCB) or other components. In certain embodiments, the size of the second solder features 114 are larger than the solder features 112 so that the tops of the solder features 112 and the second solder features 114 are generally coplanar. In certain embodiments, the metal contacts 110 and solder features 112 may be omitted from the area of the dielectric layer 107. It should be appreciated that the number, size and arrangement of the different solder features may be different than that shown in FIG. 1E, and may be any suitable combination depending on the application. However, in certain embodiments, the solder features 112 and the second solder features 114 are sized so that the tops of the bumps are coplanar allowing for electrical connections to a planar surface of a laminate substrate 120 (see, FIG. 1G).

Referring now to FIG. 1F, this figure shows a schematic cross-sectional diagram for the multichip structure 100 of FIG. 1E at a subsequent stage of the fabrication process, in accordance with embodiments. As shown in FIG. 1F, in a case where there are a plurality of different multichip structures 100 (arranged in an array) a dicing operation is performed on the multichip structure 100 to separate it from the remainder of the multichip structures, as indicated by the dashed lines and reference numeral 116. In other embodiments, when the thickness of the chips 106 is sufficiently thick, the dicing operation may be performed after the removal of the substrate 102.

Referring now to FIG. 1G, this figure shows a schematic cross-sectional diagram for the multichip structure 100 of FIG. 1F at a subsequent stage of the fabrication process, in accordance with embodiments. As shown in FIG. 1G, following the dicing operation described above with reference to FIG. 1F, the multichip structure 100 is flipped upside down and a laminate substrate 120 is attached via the solder features 112 and the second solder features 114. It should be appreciated that a reflow operation may be performed on the solder features 112 and the second solder features 114 when (or after) attaching the laminate substrate 120. The laminate substrate 120 may be comprised of any suitable material(s) that are known in the art. As also shown in FIG. 1G, the substrate 102 and the adhesive layer 104 may be removed at this stage of the manufacturing process. In certain embodiments, a width of the laminate substrate 120 (W2) is larger than a combined width (W1) of the chips 106 to allow space for a lid to cover the chips and be attached to the laminate substrate 120.

Referring now to FIG. 1H, this figure shows a schematic cross-sectional diagram for the multichip structure 100 of FIG. 1G at a subsequent stage of the fabrication process, in accordance with embodiments. As shown in FIG. 1H, a lid 122 is attached to the laminate substrate 120 and covers the multichip structure 100. The lid 122 may be a cover that has a hollow portion 164 to house the multichip structure 100 and also contact the laminate substrate 120. The vertical wall portions of the lid 122 may be formed to have a height that generally corresponds to the height of the multichip structure 100 in order to create a hermetic seal for the multichip structure 100. Thus, as shown in FIGS. 1A-1H, a simplified assembly process is achieved as compared to, for example, a silicon bridge on packaging substrate. This may allow for a higher yield than related package assembly techniques. Also, it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

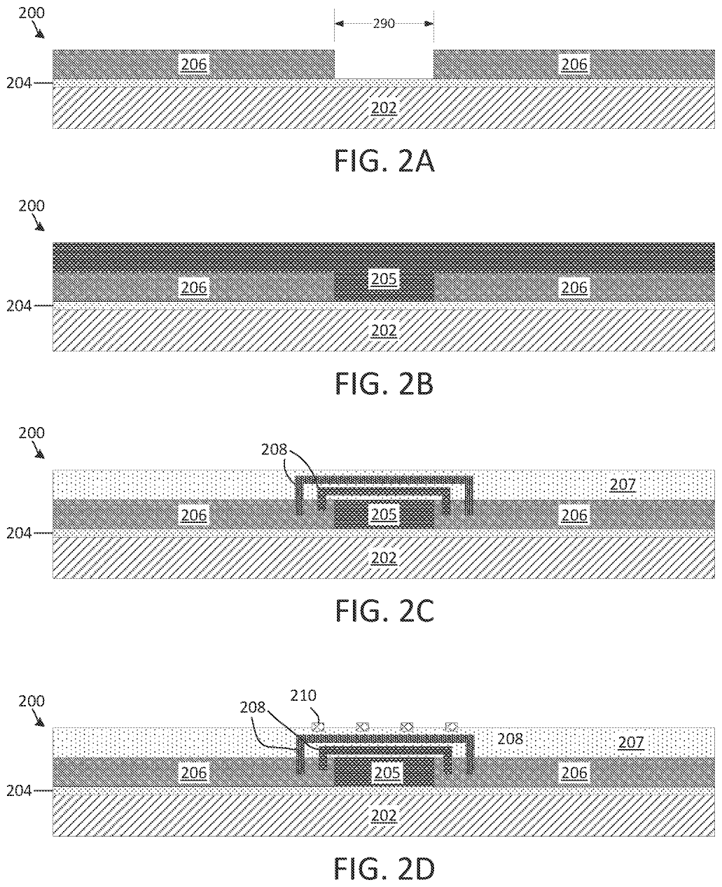

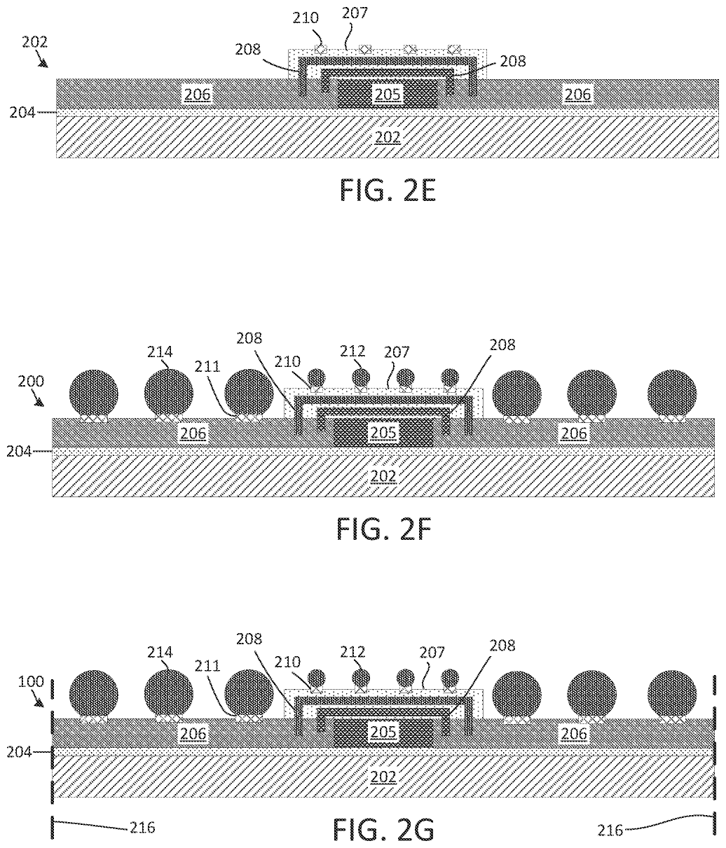

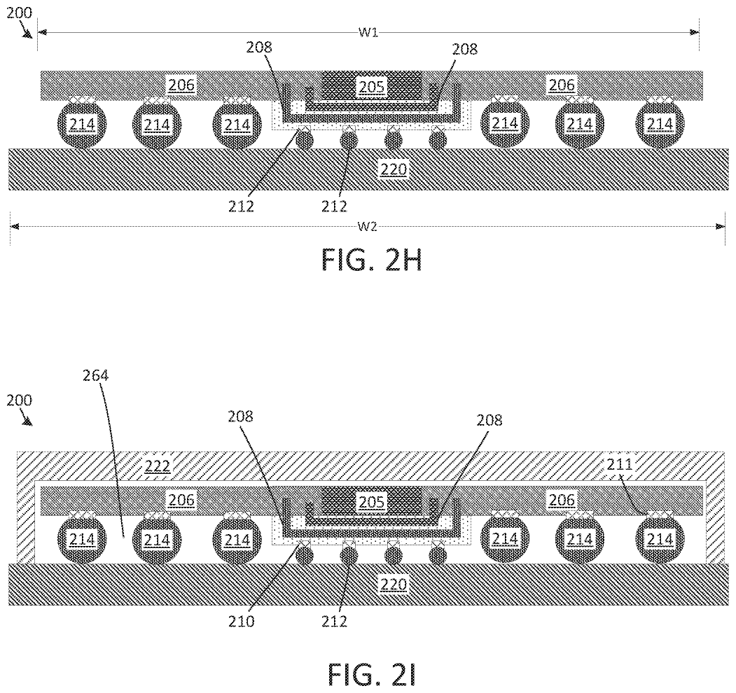

Referring now to FIG. 2A, this figure shows a schematic cross-sectional diagram for a multichip structure 200 for chip-to-chip connections at an intermediate stage of the manufacturing process, in accordance with embodiments. As shown in the multichip structure 200 of FIG. 2A, a substrate 202 is provided. As an example, the substrate 202 (or carrier wafer) can be a traditional organic substrate as known in the art, or any other suitable material(s). In certain embodiments, an adhesive layer 204 is provided on the substrate 202. The adhesive layer 204 may be comprised on any suitable material(s) and allows for the different chips 206 to be mounted to the substrate 202. Two physically separate chips 206 are mounted on the substrate 202 with some distance therebetween. The chips 206 may be of the same type or different types (e.g., a first die may be a memory die and a second die may be a logic die). In certain examples, the chips 206 are separated from each other by about 10 μm or more to create a space (or a trench 290) therebetween. In certain examples, the chips 206 are reconstituted and thinned chips.

Referring now to FIG. 2B, this figure shows a schematic cross-sectional diagram for the multichip structure 200 of FIG. 2A at a subsequent stage of the fabrication process, in accordance with embodiments. As shown in FIG. 2B, a molding compound 205 (e.g., an epoxy mold compound (EMC)) is formed over and between the chips 206. The molding compound 205 may bind the chips 206 together. In certain embodiments, the molding compound 205 may initially be formed in excess above the chips 206.

Referring now to FIG. 2C, this figure shows a schematic cross-sectional diagram for the multichip structure 200 of FIG. 2B at a subsequent stage of the fabrication process, in accordance with embodiments. As shown in FIG. 2C, any excess material of the molding compound 205 may be removed with any suitable material removal process (e.g., CMP). Then, a dielectric layer 207 is deposited over the chips 206 and the molding compound 205. The dielectric layer 207 may be, for example, an oxide layer. In one example, the dielectric layer 207 comprises one or more of the following; SiO₂, SiN, SiCN, a polymer, an epoxy, or a suitable organic material. In an example, one or more organic oxide materials are used for the dielectric layer 207 that allow for low temperature (e.g., 175° C.) deposition. In certain examples, a height (or thickness) of the dielectric layer 207 above the upper surfaces of the chips 206 may be from 10-60 μm. This thickness of the dielectric layer 207 allows for conductor lines (or traces, or metal lines) to be formed in the dielectric layer 207 to connect the chips 206. As shown in FIG. 2C, through-dielectric vias 208 (or electrically conductive traces, or conductor lines, or metal lines) are formed in the dielectric layer 207 with any suitable combination of patterning, material deposition and material removal steps. The through-dielectric vias 208 may be formed in a similar manner as the through-dielectric vias 108 discussed above with respect to FIG. 1B. The through-dielectric vias 208 (or conductor lines) may be comprised of any suitable conductive material (e.g., copper). In an example, a ratio of the height (or thickness) of the dielectric layer 207 above the surface of the adhesive layer 204 to the distance between the chips 206 is about 1:1. However, it should be appreciated that other suitable ratios of the height to separation distance may be used.

Referring now to FIG. 2D, this figure shows a schematic cross-sectional diagram for the multichip structure 200 of FIG. 2C at a subsequent stage of the fabrication process, in accordance with embodiments. As shown in FIG. 2D, metal contacts 210 (or pads, or under bump metal layers) are formed on the dielectric layer 207 on or above the through-dielectric vias 208. The metal contacts 210 are configured to accept solder bumps (discussed in detail below) at a later stage of the manufacturing process. Thus, the process described above with respect to FIGS. 2A-2D differs from the embodiments of FIGS. 1A-1H in that there is a molding compound 205 layer between the chips 206 rather than the additional material of the dielectric layer 107 shown in FIG. 1C. The molding compound 205 may provide a higher structural support during handing and processing, as compared to a more fragile oxide layer in a case where the bridge is on the bottom.

Referring now to 2E, this figure shows a schematic cross-sectional diagram for the dielectric multichip structure 200 of FIG. 2D at a subsequent stage of the fabrication process, in accordance with embodiments. As shown in FIG. 2E, in certain examples, the dielectric layer 207 is initially deposited over the entire surfaced of the multichip structure 200, and then any suitable patterning and material removal processes (e.g., an oxide etching process) may be used to remove portions of the dielectric layer 207 over the chips 206 (while maintaining some overlap over the chips 206 to allow for the formation of the wirings and the through-dielectric vias 208 that connect the chips 206 together). As shown in FIG. 2D, the through-dielectric vias 208 and the dielectric layer 207 form electrical connections (e.g., BEOL wirings) between the two different chips 206.

Referring now to FIG. 2F, this figure shows a schematic cross-sectional diagram for the multichip structure 100 of FIG. 2E at a subsequent stage of the fabrication process, in accordance with embodiments. As shown in FIG. 2F, in an embodiments, a number of second metal contacts 211 (or pads, or under bump metal layers) are formed on the chips 206. These second metal contacts 211 may be comprised of the same or different materials than the metal contacts 210, and may be sized to be larger than the metal contacts 210 to be able to accept a larger solder feature than the metal contacts 210. A number of solder features 212 are formed on the metal contacts 210, and a number of second solder features 214 are formed on the second metal contacts 211. In an embodiment, the solder features 212 and the second solder features 214 are solder balls from a ball grid array (BGA). As shown, the solder features 212 and the second solder features 214 may permit the microchip structure 200 to be mounted and electrically coupled to, for example, an underlying printed circuit board (PCB) or other components. In certain embodiments, the size of the second solder features 214 are larger than the solder features 212 so that the tops of the solder features 212 and the second solder features 214 are generally coplanar. In certain embodiments, the metal contacts 210 and solder features 212 may be omitted from the area of the dielectric layer 207. It should be appreciated that the number, size and arrangement of the different solder features may be different than that shown in FIG. 2F, and may be any suitable combination depending on the application.

Referring now to FIG. 2G, this figure shows a schematic cross-sectional diagram for the multichip structure 200 of FIG. 2F at a subsequent stage of the fabrication process, in accordance with embodiments. As shown in FIG. 2G, in a case where there are a plurality of different multichip structures 200 (arranged in an array) a dicing operation is performed on the multichip structure 200 to separate it from the remainder of the multichip structures, as indicated by the dashed lines and reference numeral 216. In other embodiments, when the thickness of the chips 206 is sufficiently thick, the dicing operation may be performed after the removal of the substrate 202.

Referring now to FIG. 2H, this figure shows a schematic cross-sectional diagram for the multichip structure 100 of FIG. 2G at a subsequent stage of the fabrication process, in accordance with embodiments. As shown in FIG. 2H, following the dicing operation described above with reference to FIG. 2G, the multichip structure 200 is flipped upside down and a laminate substrate 220 is attached via the solder features 212 and the second solder features 214. It should be appreciated that a reflow operation may be performed on the solder features 212 and the second solder features 214 when (or after) attaching the laminate substrate 220. The laminate substrate 220 may be comprised of any suitable material(s) that are known in the art. As also shown in FIG. 2H, the substrate 202 and the adhesive layer 204 may be removed at this stage of the manufacturing process. In certain embodiments, a width of the laminate substrate 220 (W2) is larger than a combined width (W1) of the chips 206 to allow space for a lid to cover the chips 206 and be attached to the laminate substrate 220.

Referring now to FIG. 2I, this figure shows a schematic cross-sectional diagram for the multichip structure 100 of FIG. 2H at a subsequent stage of the fabrication process, in accordance with embodiments. As shown in FIG. 2I, a lid 222 is attached to the laminate substrate 220 and covers the multichip structure 200. The lid 222 may be a cover that has a hollow portion 264 to house the multichip structure 200 and also contact the laminate substrate 220. The vertical wall portions of the lid 222 may be formed to have a height that generally corresponds to the height of the multichip structure 200 in order to create a hermetic seal for the multichip structure 200. Thus, as shown in FIGS. 2A-2I, a simplified assembly process is achieved as compared to, for example, a silicon bridge on packaging substrate. Similar to the embodiments described above with respect to FIGS. 1A-1H, this may allow for a higher yield than related package assembly techniques, and it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

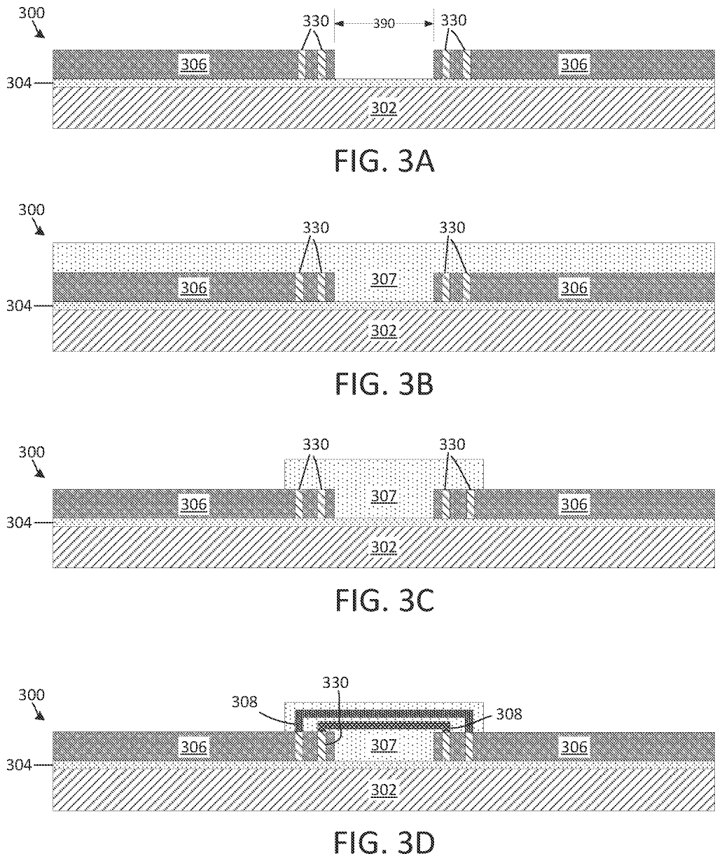

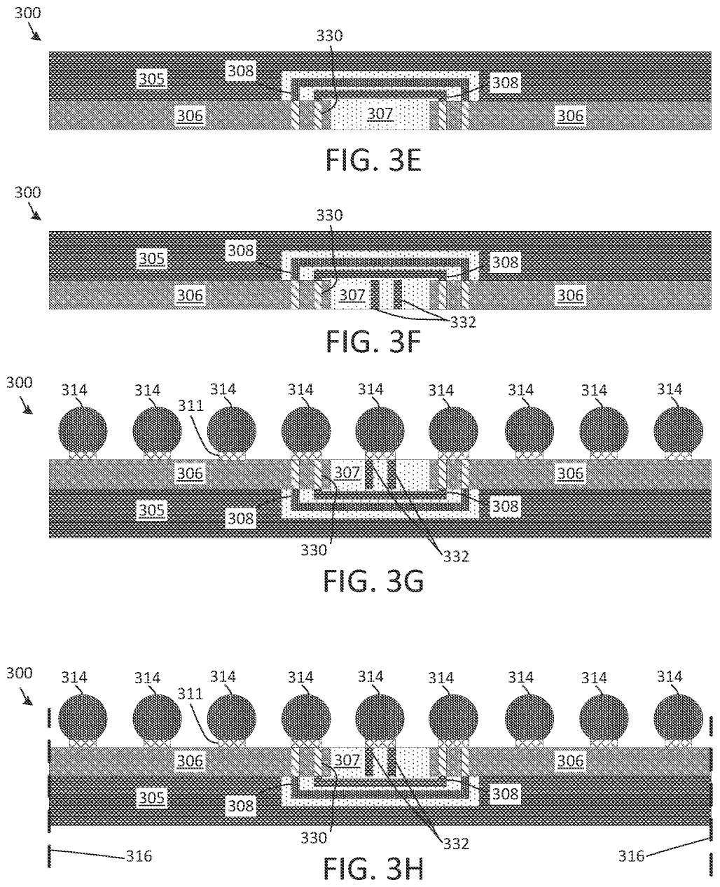

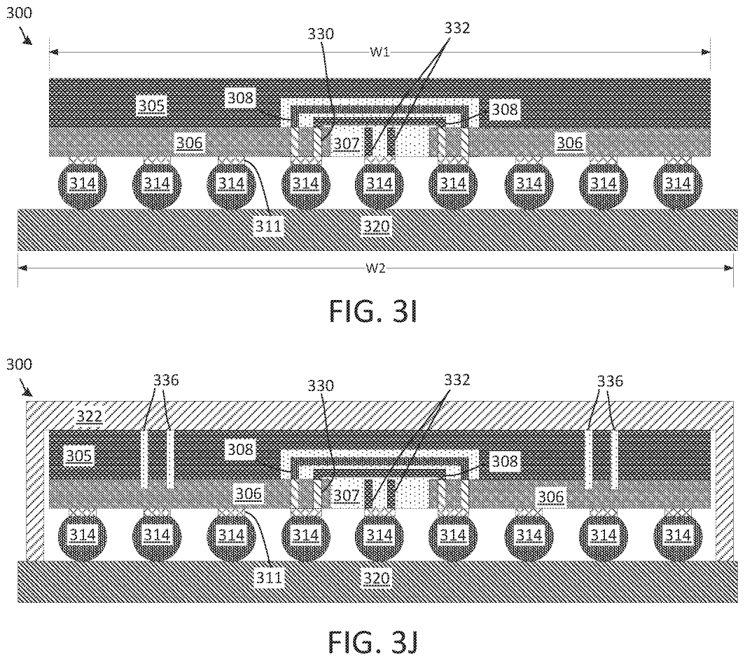

Referring now to FIG. 3A, this figure shows a schematic cross-sectional diagram for a multichip structure 300 for chip-to-chip connections at an intermediate stage of the manufacturing process, in accordance with embodiments. In certain of these embodiments, the dielectric bridge structure (or dielectric layer 307) is formed on a top side of the multichip structure 300 (as opposed to the dielectric layer 107 being formed on the bottom side of the multichip structure 100 as shown in FIG. 1H). As shown in the multichip structure 300 of FIG. 3A, a substrate 302 is provided. As an example, the substrate 302 (or carrier wafer) can be a traditional organic substrate as known in the art, or any other suitable material(s). In certain embodiments, an adhesive layer 304 is provided on the substrate 302. The adhesive layer 304 may be comprised on any suitable material(s) and allows for the different chips 306 to be mounted to the substrate 302. Two different and physically separate chips 306 are mounted on the substrate 302 with some distance therebetween. The chips 306 may be of the same type or different types (e.g., a first die may be a memory die and a second die may be a logic die). In certain examples, the chips 306 are separated from each other by about 10 μm or more to create a space (or a trench 390) therebetween. In certain examples, the chips 306 are reconstituted and thinned chips. As shown in FIG. 3A, through-chip vias 330 are formed in each of the different chips 306. The through-chip vias 330 may be formed by a combination of patterning a photoresist layer, then using a material removal process (e.g., reactive ion etching or RIE) to form holes through the chips 306, and then using a material deposition process to fill the holes with a conductive metal material to form the through-chip vias 330. The through-chip vias 330 may comprise one or more suitable conductive materials (e.g., copper).

Referring now to 3B, this figure shows a schematic cross-sectional diagram for the multichip structure 300 of FIG. 3A at a subsequent stage of the fabrication process, in accordance with embodiments. As shown in FIG. 3B, a dielectric layer 307 is deposited over and between the chips 306. The dielectric layer 307 may be, for example, an oxide layer. In one example, the dielectric layer 307 comprises one or more of the following; SiO₂, SiN, SiCN, a polymer, an epoxy, or a suitable organic material. In an example, one or more organic oxide materials are used for the dielectric layer 307 that allow for low temperature (e.g., 175° C.) deposition. In certain examples, a height (or thickness) of the dielectric layer 307 above the upper surfaces of the chips 106 may be from 10-60 μm. This thickness of the dielectric layer 307 allows for conductor lines or metal traces (discussed in further detail below) to be formed in the dielectric layer 307 to connect the chips 306. In certain examples, the dielectric layer 307 is initially deposited over the entire surfaced of the multichip structure 300, and then any suitable patterning and material removal processes may be used to remove portions of the dielectric layer 307 over the chips 306 (which maintain some overlap over the chips 306 and the through-chip vias 330 to allow for subsequent formation of the wirings and the through-dielectric vias that connect the chips 306 together). In an example, a ratio of the height (or thickness) of the dielectric layer 307 above the surface of the adhesive layer 304 to the distance between the chips 306 is about 1:1. However, it should be appreciated that other suitable ratios of the height to separation distance may be used.

Referring now to FIG. 3C, this figure shows a schematic cross-sectional diagram for the multichip structure 300 of FIG. 3B at a subsequent stage of the fabrication process, in accordance with embodiments. As shown in FIG. 3C, suitable patterning and etching processes (e.g., oxide etching) may be performed to remove portions of the dielectric layer 307 above the chips 306. These processes result in the bridge structure of the dielectric layer 307, where the dielectric layer 307 fills in the space (or trench 390, or gap as shown in FIG. 3A) between the chips 306, and also overlaps portions of the chips 306 to allow for subsequent formation of the conductive lines therein that connect to the through-chip vias 330.

Referring now to 3D, this figure shows a schematic cross-sectional diagram for the multichip structure 300 of FIG. 3C at a subsequent stage of the fabrication process, in accordance with embodiments. As shown in FIG. 3D, through-dielectric vias 308 are formed in the dielectric layer 307 with any suitable combination of patterning, material deposition and material removal steps. The through-dielectric vias 308 (or conductor lines) may be comprised of any suitable conductive material (e.g., copper). As shown in FIG. 3D, the through-dielectric vias 308 and through-chip vias 330 form electrical connections (e.g., BEOL wirings) between the two different chips 306.

Referring now to FIG. 3E, this figure shows a schematic cross-sectional diagram for the multichip structure 300 of FIG. 3D at a subsequent stage of the fabrication process, in accordance with embodiments. As shown in FIG. 3E, a molding compound 305 (e.g., an epoxy mold compound (EMC)) is formed over the chips 306 and the dielectric layer 307. The molding compound 305 may bind the chips 306 together. In certain embodiments, the molding compound 305 may initially be formed in excess above the chips 306. As also shown in FIG. 3E, in certain embodiments, the substrate 302 and adhesive layer 304 are removed at this stage of the manufacturing process.

Referring now to FIG. 3F, this figure shows a schematic cross-sectional diagram for the multichip structure 300 of FIG. 3E at a subsequent stage of the fabrication process, in accordance with embodiments. As shown in FIG. 3F, in certain embodiments, through-dielectric vias 332 are formed through the dielectric layer 307. It should be appreciated that in some other embodiments (e.g., in the embodiments of FIGS. 1 and 2), the through-dielectric vias 332 are not formed. The through-dielectric vias 332 (or conductor lines) may be comprised of any suitable conductive material (e.g., copper).

Referring now to FIG. 3G, this figure shows a schematic cross-sectional diagram for the multichip structure 300 of FIG. 3F at a subsequent stage of the fabrication process, in accordance with embodiments. As shown in FIG. 3G, metal contacts 311 (or pads, or under bump metal layers) are formed on the dielectric layer 307 on or above the through-dielectric vias 332. The metal contacts 311 are configured to accept solder bumps (discussed in detail below) at a later stage of the manufacturing process. In certain embodiments, additional metal contacts 311 are formed on top of the chips 306. Then, a number of solder features 314 are formed on the metal contacts 311. In an embodiment, the solder features 314 are solder balls from a ball grid array (BGA). As shown, the solder features 314 may permit the microchip structure 300 to be mounted and electrically coupled to, for example, an underlying printed circuit board (PCB) or other components. In certain embodiments, the tops of the solder features 314 are generally coplanar. In certain embodiments, the metal contacts 311 and the solder features 314 may be omitted from the area of the dielectric layer 307. It should be appreciated that the number, size and arrangement of the different solder features may be different than that shown in FIG. 3G, and may be any suitable combination depending on the application.

Referring now to FIG. 3H, this figure shows a schematic cross-sectional diagram for the multichip structure 300 of FIG. 3G at a subsequent stage of the fabrication process, in accordance with embodiments. As shown in FIG. 3H, in a case where there are a plurality of different multichip structures 300 (arranged in an array) a dicing operation is performed on the multichip structure 300 to separate it from the remainder of the multichip structures, as indicated by the dashed lines and reference numeral 316. In other embodiments, when the thickness of the chips 306 is sufficiently thick, the dicing operation may be performed after the removal of the substrate 302. In certain embodiments, a suitable material removal process (e.g., CMP) may be used to thin the molding compound 305 (not shown) so that the dielectric layer 307 is exposed.

Referring now to FIG. 3I, this figure shows a schematic cross-sectional diagram for the multichip structure 300 of FIG. 3H at a subsequent stage of the fabrication process, in accordance with embodiments. As shown in FIG. 3I, following the dicing operation described above with reference to FIG. 3H, the multichip structure 300 is flipped upside down and a laminate substrate 320 is attached via the solder features 314. It should be appreciated that a reflow operation may be performed on the solder features 314 when (or after) attaching the laminate substrate 320. The laminate substrate 320 may be comprised of any suitable material(s) that are known in the art. In certain embodiments, a width of the laminate substrate 320 (W2) is larger than a combined width (W1) of the chips 306 to allow space for a lid to cover the chips 306 and be attached to the laminate substrate 320.

Referring now to FIG. 3J, this figure shows a schematic cross-sectional diagram for the multichip structure 300 of FIG. 3I at a subsequent stage of the fabrication process, in accordance with embodiments. As shown in FIG. 3J, a lid 322 is attached to the laminate substrate 320 and covers the multichip structure 300. The lid 322 may be a cover that has a hollow portion 364 to house the multichip structure 300 and also contact the laminate substrate 320. The vertical wall portions of the lid 322 may be formed to have a height that generally corresponds to the height of the multichip structure 300 in order to create a hermetic seal for the multichip structure 300. Also, in certain embodiments, heat extraction vias 336 may be formed through the molding compound 305 to provide a structure between the chips 306 and the lid 322 that allows for efficient heat transfer from the chips 306 to the lid 322. The chips 306 (or the first die and the second die) are arranged between the through-dielectric vias 308 and the molding compound 305, and the substrate 320. Thus, as shown in FIGS. 3A-3J, a simplified assembly process is achieved as compared to, for example, a silicon bridge on packaging substrate. Similar to the embodiments described above with respect to FIGS. 1A-1H, this may allow for a higher yield than related package assembly techniques, and it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

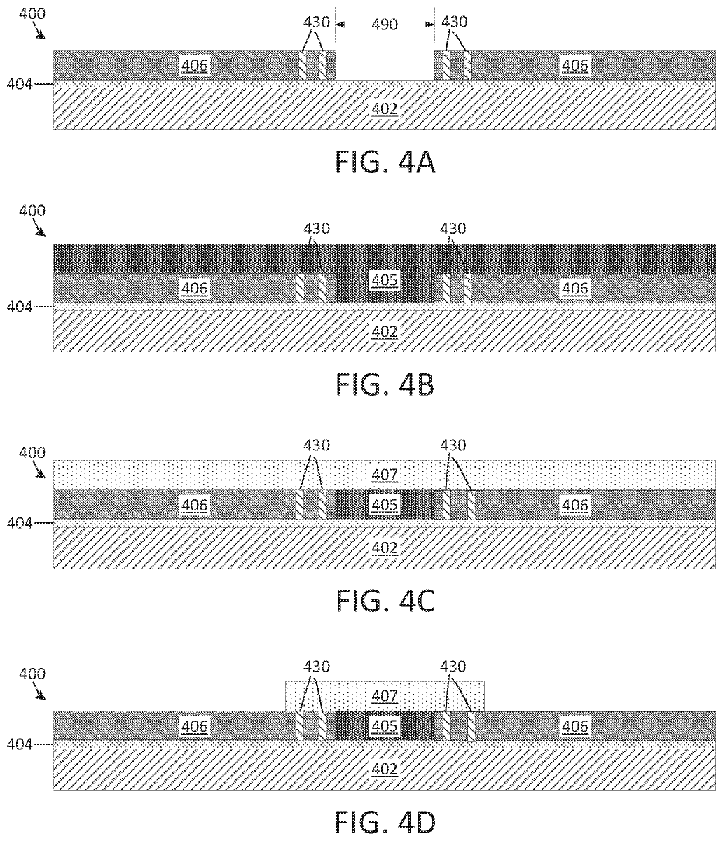

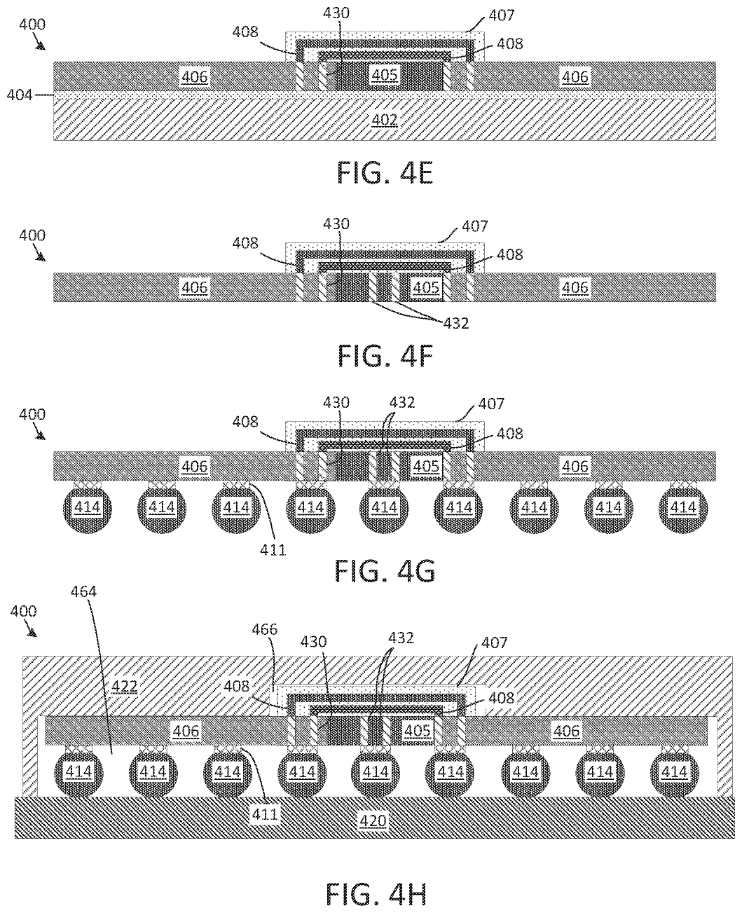

Referring now to FIG. 4A, this figure shows a schematic cross-sectional diagram for a multichip structure 400 for chip-to-chip connections at an intermediate stage of the manufacturing process, in accordance with embodiments. In certain of these embodiments, the dielectric bridge structure including the dielectric layer 407 is formed on a top side of the multichip structure 400 (as opposed to the dielectric layer 107 being formed on the bottom side of the multichip structure 100 as shown in FIG. 1H). As shown in the multichip structure 400 of FIG. 4A, a substrate 402 is provided. As an example, the substrate 402 (or carrier wafer) can be a traditional organic substrate as known in the art, or any other suitable material(s). In certain embodiments, an adhesive layer 404 is provided on the substrate 402. The adhesive layer 404 may be comprised on any suitable material(s) and allows for the different chips 406 to be mounted to the substrate 402. Two different and physically separate chips 406 are mounted on the substrate 402 with some distance therebetween. The chips 406 may be of the same type or different types (e.g., a first die may be a memory die and a second die may be a logic die). In certain examples, the chips 406 are separated from each other by about 10 μm or more to create a space (or a trench 490) therebetween. In certain examples, the chips 406 are reconstituted and thinned chips. As shown in FIG. 4A, through-chip vias 430 are formed in each of the different chips 406. The through-chip vias 430 may comprise one or more suitable conductive materials (e.g., copper).

Referring now to FIG. 4B, this figure shows a schematic cross-sectional diagram for the multichip structure 400 of FIG. 4A at a subsequent stage of the fabrication process, in accordance with embodiments. As shown in FIG. 4B, a molding compound 405 (e.g., an epoxy mold compound (EMC)) is formed over and between the chips 406. The molding compound 405 may bind the chips 406 together. In certain embodiments, the molding compound 405 may initially be formed in excess above the chips 406, and any excess material of the molding compound 405 may be removed with any suitable material removal process (e.g., CMP).

Referring now to FIG. 4C, this figure shows a schematic cross-sectional diagram for the multichip structure 400 of FIG. 4B at a subsequent stage of the fabrication process, in accordance with embodiments. As shown in FIG. 4C, after the molding compound 405 is thinned with, for example, a CMP process to make an upper surface of the molding compound 405 generally coplanar with the upper surfaces of the chip 406, a dielectric layer 407 is deposited over the chips 406 and the molding compound 405. The dielectric layer 407 may be, for example, an oxide layer. In one example, the dielectric layer 407 comprises one or more of the following; SiO₂, SiN, SiCN, a polymer, an epoxy, or a suitable organic material. In an example, one or more organic oxide materials are used for the dielectric layer 407 that allow for low temperature (e.g., 175° C.) deposition. In certain examples, a height (or thickness) of the dielectric layer 407 above the upper surfaces of the chips 406 may be from 10-60 μm. This thickness of the dielectric layer 407 allows for conductor lines (discussed in further detail below) to be formed in the dielectric layer 407 to connect the chips 406. In an example, a ratio of the height (or thickness) of the dielectric layer 407 above the surface of the adhesive layer 404 to the distance between the chips 406 is about 1:1. However, it should be appreciated that other suitable ratios of the height to separation distance may be used.

Referring now to 4D, this figure shows a schematic cross-sectional diagram for the multichip structure 400 of FIG. 4C at a subsequent stage of the fabrication process, in accordance with embodiments. As shown in FIG. 4D, in certain examples, the dielectric layer 407 is initially deposited over the entire surfaced of the multichip structure 400, and then any suitable patterning and material removal processes (e.g., an oxide etching process) may be used to remove portions of the dielectric layer 407 over the chips 406 (while maintaining some overlap over the chips 406 to allow for subsequent formation of the wirings and the through-dielectric vias that connect the chips 406 together). Thus, the process described above with respect to FIGS. 4A-4D differs from the embodiments of FIGS. 1A-1H in that there is a molding compound 405 layer between the chips 406 rather than the additional material of the dielectric layer 107 shown in FIG. 1C. Also, the dielectric bridge structure including the dielectric layer 407 is formed on the top side (i.e., the opposite side of the chips 406 relative to where the solder bumps will be formed).

Referring now to FIG. 4E, this figure shows a schematic cross-sectional diagram for the multichip structure 400 of FIG. 4D at a subsequent stage of the fabrication process, in accordance with embodiments. As shown in FIG. 4D, through-dielectric vias 408 are formed in the dielectric layer 407 with any suitable combination of patterning, material deposition and material removal steps. The through-dielectric vias 408 (or conductor lines) may be comprised of any suitable conductive material (e.g., copper). As shown in FIG. 4D, the through-dielectric vias 408 and through-chip vias 430 form electrical connections (e.g., BEOL wirings) between the two different chips 406.

Referring now to FIG. 4F, this figure shows a schematic cross-sectional diagram for the multichip structure 400 of FIG. 4E at a subsequent stage of the fabrication process, in accordance with embodiments. As shown in FIG. 4F, in certain embodiments, through-dielectric vias 432 are formed through the dielectric layer 407. It should be appreciated that in other embodiments, the through-dielectric vias 432 are not formed. The through-dielectric vias 432 (or conductor lines) may be comprised of any suitable conductive material (e.g., copper). As also shown in FIG. 4F, the substrate 402 and the adhesive layer 404 are removed.

Referring now to FIG. 4G, this figure shows a schematic cross-sectional diagram for the multichip structure 400 of FIG. 4F at a subsequent stage of the fabrication process, in accordance with embodiments. As shown in FIG. 4G, metal contacts 411 (or pads, or under bump metal layers) are formed on the dielectric layer 407 on or above the through-dielectric vias 432. The metal contacts 411 are configured to accept solder bumps (discussed in detail below) at a later stage of the manufacturing process. In certain embodiments, additional metal contacts 411 are formed on top of the chips 406. Then, a number of solder features 414 are formed on the metal contacts 411. In an embodiment, the solder features 414 are solder balls from a ball grid array (BGA). As shown, the solder features 414 may permit the microchip structure 400 to be mounted and electrically coupled to, for example, an underlying printed circuit board (PCB) or other components. In certain embodiments, the tops of the solder features 414 are generally coplanar. In certain embodiments, the metal contacts 411 and the solder features 414 may be omitted from the area of the dielectric layer 407. It should be appreciated that the number, size and arrangement of the different solder features 414 may be different than that shown in FIG. 4G, and may be any suitable combination depending on the application. Although not shown in FIG. 4G, a dicing operation may be performed on the multichip structure 400 to separate it from the remainder of the multichip structures.

Referring now to FIG. 4H, this figure shows a schematic cross-sectional diagram for the multichip structure 400 of FIG. 4G at a subsequent stage of the fabrication process, in accordance with embodiments. As shown in FIG. 4H, following the dicing operation described above, the multichip structure 400 is flipped upside down and a laminate substrate 420 is attached via the solder features 414. It should be appreciated that a reflow operation may be performed on the solder features 414 when (or after) attaching the laminate substrate 420. The laminate substrate 420 may be comprised of any suitable material(s) that are known in the art. In certain embodiments, a width of the laminate substrate 420 (W2) is larger than a combined width (W1) of the chips 406 to allow space for a lid 422 to cover the chips 406 and be attached to the laminate substrate 420. As also shown in FIG. 4H, the lid 422 is attached to the laminate substrate 420 and covers the multichip structure 400. The lid 422 may be a cover that has a hollow portion 464 to house the multichip structure 400 and also contact the laminate substrate 420. The vertical wall portions of the lid 422 may be formed to have a height that generally corresponds to the height of the multichip structure 400 in order to create a hermetic seal for the multichip structure 400. Also, the lid 422 may include a secondary hollow portion 466 to house the dielectric layer 407 and through-dielectric vias 408. In certain examples, the secondary hollow portion 466 is sized to allow for a slight gap between the top of the dielectric layer 407 and the lid 422, thus applying some pressure to the multichip structure 400 without applying pressure to the dielectric layer 407. In other examples, the secondary hollow portion 466 is sized so that the top of the dielectric layer 407 contacts the lid 422. Thus, as shown in FIGS. 4A-4H, a simplified assembly process is achieved as compared to, for example, a silicon bridge on packaging substrate. Similar to the embodiments described above with respect to FIGS. 1A-1H, this may allow for a higher yield than related package assembly techniques, and it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

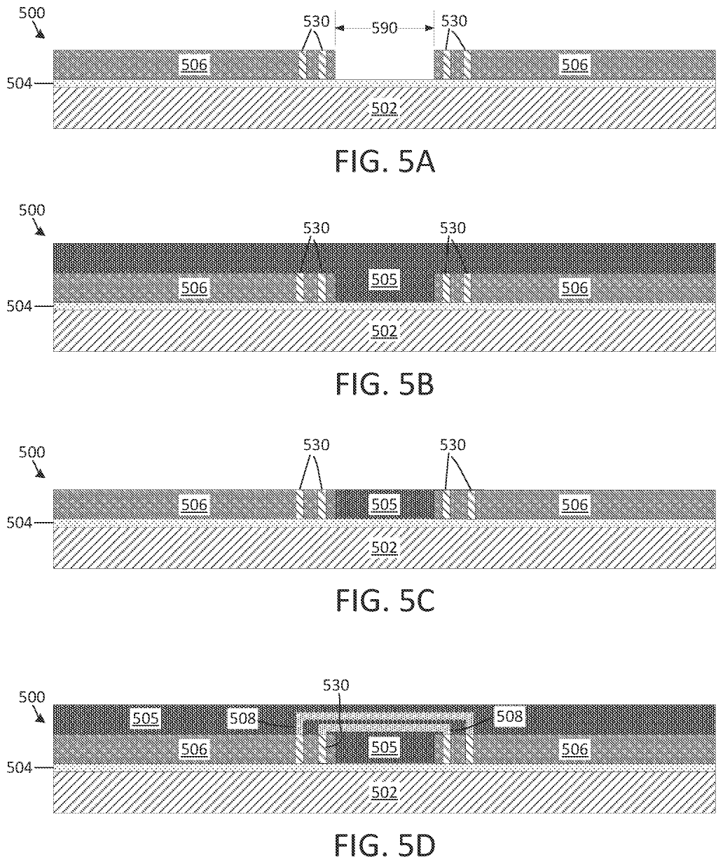

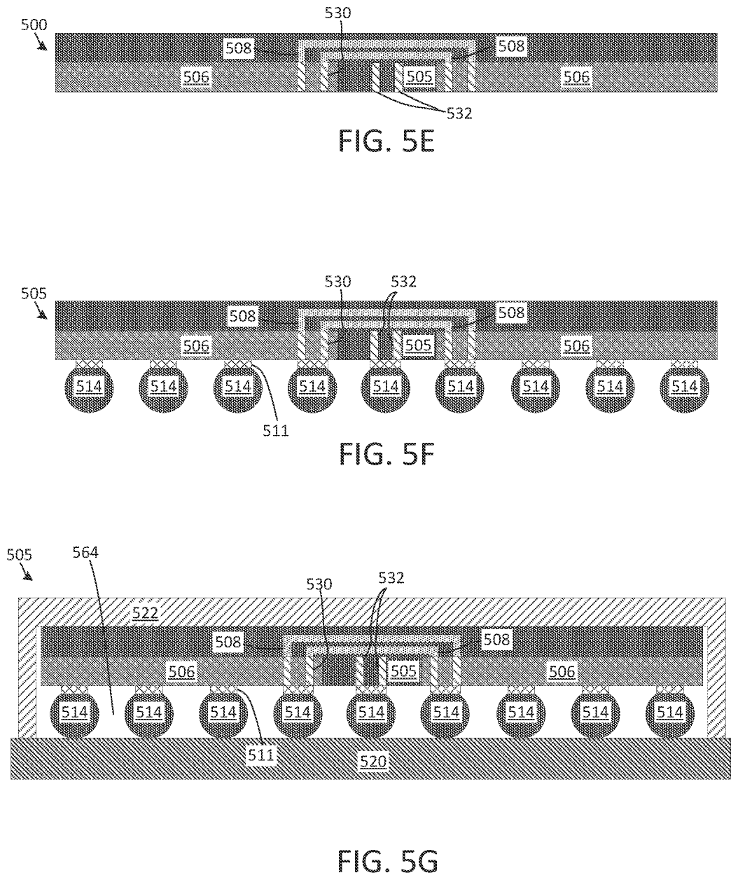

Referring now to FIG. 5A, this figure shows a schematic cross-sectional diagram for a multichip structure 500 for chip-to-chip connections at an intermediate stage of the manufacturing process, in accordance with embodiments. In certain of these embodiments, the dielectric bridge structure is formed on a top side of the multichip structure 500, and the dielectric bridge structure is formed in the molding compound layer rather than the dielectric layers discussed above. As shown in the multichip structure 500 of FIG. 5A, a substrate 502 is provided. As an example, the substrate 502 (or carrier wafer) can be a traditional organic substrate as known in the art, or any other suitable material(s). In certain embodiments, an adhesive layer 504 is provided on the substrate 502. The adhesive layer 504 may be comprised on any suitable material(s) and allows for the different chips 506 to be mounted to the substrate 502. Two different and physically separate chips 506 are mounted on the substrate 502 with some distance therebetween. The chips 506 may be of the same type or different types (e.g., a first die may be a memory die and a second die may be a logic die). In certain examples, the chips 506 are separated from each other by about 10 μm or more to create a space (or a trench 590) therebetween. In certain examples, the chips 506 are reconstituted and thinned chips. As shown in FIG. 5A, through-chip vias 530 are formed in each of the different chips 506. The through-chip vias 530 may comprise one or more suitable conductive materials (e.g., copper).

Referring now to FIG. 5B, this figure shows a schematic cross-sectional diagram for the multichip structure 500 of FIG. 5A at a subsequent stage of the fabrication process, in accordance with embodiments. As shown in FIG. 5B, a molding compound 505 (e.g., an epoxy mold compound (EMC)) is formed over and between the chips 506. The molding compound 505 may bind the chips 506 together.

Referring now to FIG. 5C, this figure shows a schematic cross-sectional diagram for the multichip structure 500 of FIG. 5B at a subsequent stage of the fabrication process, in accordance with embodiments. As shown in FIG. 5C, in certain embodiments, the molding compound 505 may initially be formed in excess above the chips 506, and any excess material of the molding compound 505 may be removed with any suitable material removal process (e.g., CMP).

Referring now to FIG. 5D, this figure shows a schematic cross-sectional diagram for the multichip structure 500 of FIG. 5C at a subsequent stage of the fabrication process, in accordance with embodiments. As shown in FIG. 5D, through-molding compound vias 508 are formed in additional material of the molding compound 505 layer with any suitable combination of patterning, material deposition and material removal steps. The through-molding compound vias 508 (or conductor lines) may be comprised of any suitable conductive material (e.g., copper). As shown in FIG. 5D, the through-molding compound vias 508 and through-chip vias 530 form electrical connections (e.g., BEOL wirings) between the two different chips 506, and they are embedded in the additional material of the molding compound 505 which covers the entire surface of the chips 506.

Referring now to FIG. 5E, this figure shows a schematic cross-sectional diagram for the multichip structure 100 of FIG. 5D at a subsequent stage of the fabrication process, in accordance with embodiments. As shown in FIG. 5E, in certain embodiments, through-molding compound vias 532 are formed through the molding compound 505 is the area between the chips 506. It should be appreciated that in other embodiments, the through-molding compound vias 532 are not formed. The through-molding compound vias 532 (or conductor lines) may be comprised of any suitable conductive material (e.g., copper). As also shown in FIG. 5E, the substrate 502 and the adhesive layer 504 are removed.

Referring now to FIG. 5F, this figure shows a schematic cross-sectional diagram for the multichip structure 100 of FIG. 5E at a subsequent stage of the fabrication process, in accordance with embodiments. As shown in FIG. 5F, metal contacts 511 (or pads, or under bump metal layers) are formed on the dielectric layer 507 on or above the through-dielectric vias 532. The metal contacts 511 are configured to accept solder bumps (discussed in detail below) at a later stage of the manufacturing process. In certain embodiments, additional metal contacts 511 are formed on top of the chips 506. Then, a number of solder features 514 are formed on the metal contacts 511. In an embodiment, the solder features 514 are solder balls from a ball grid array (BGA). As shown, the solder features 514 may permit the microchip structure 500 to be mounted and electrically coupled to, for example, an underlying printed circuit board (PCB) or other components. In certain embodiments, the bottoms of the solder features 514 are generally coplanar. In certain embodiments, the metal contacts 511 and the solder features 514 may be omitted from the area of the molding compound 505 that is between the chips 506. It should be appreciated that the number, size and arrangement of the different solder features 514 may be different than that shown in FIG. 5F, and may be any suitable combination depending on the application. Although not shown in FIG. 5F, a dicing operation may be performed on the multichip structure 500 to separate it from the remainder of the multichip structures.

Referring now to FIG. 5G, this figure shows a schematic cross-sectional diagram for the multichip structure 100 of FIG. 5F at a subsequent stage of the fabrication process, in accordance with embodiments. As shown in FIG. 5G, following the dicing operation described above, a laminate substrate 520 is attached to the multichip structure 500 via the solder features 514. It should be appreciated that a reflow operation may be performed on the solder features 514 when (or after) attaching the laminate substrate 520. The laminate substrate 520 may be comprised of any suitable material(s) that are known in the art. In certain embodiments, a width of the laminate substrate 520 (W2) is larger than a combined width (W1) of the chips 506 to allow space for a lid to cover the chips 506 and be attached to the laminate substrate 520. As also shown in FIG. 5G, the lid 522 is attached to the laminate substrate 520 and covers the multichip structure 500. The lid 522 may be a cover that has a hollow portion 564 to house the multichip structure 500 and also contact the laminate substrate 520. The vertical wall portions of the lid 522 may be formed to have a height that generally corresponds to the height of the multichip structure 500 in order to create a hermetic seal for the multichip structure 500. Thus, as shown in FIGS. 5A-5G, a simplified assembly process is achieved (i.e., utilizing the molding compound 505 as the dielectric bridge structure) as compared to, for example, a silicon bridge on packaging substrate. Similar to the embodiments described above with respect to FIGS. 1A-1H, this may allow for a higher yield than related package assembly techniques, and it is not necessary to utilize a silicon bridge, which may allow for the inter-die connection pathways to have shorter travel distances, a lower energy requirement (e.g., pJ/bit) for the communication, a higher latency, and/or a higher bandwidth than related structures.

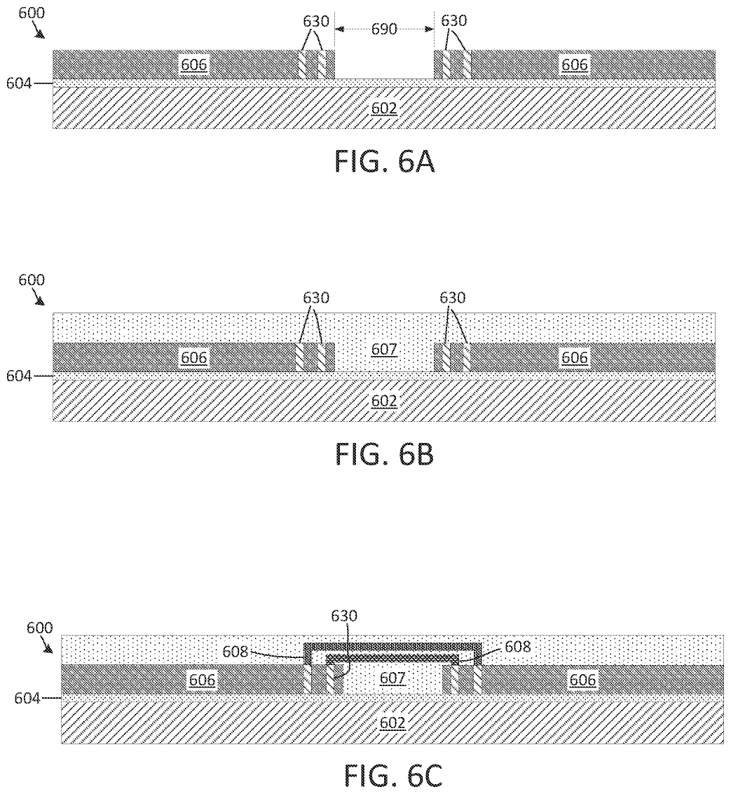

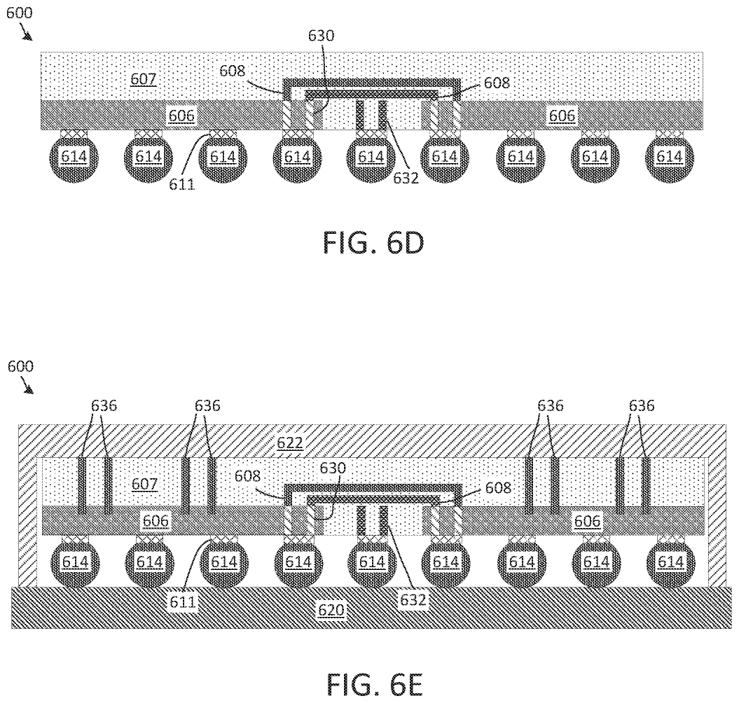

Referring now to FIG. 6A, this figure shows a schematic cross-sectional diagram for a multichip structure 600 for chip-to-chip connections at an intermediate stage of the manufacturing process, in accordance with embodiments. In certain of these embodiments, the dielectric bridge structure (or dielectric layer 607) is formed on a top side of the multichip structure 600 (as opposed to the dielectric layer 107 being formed on the bottom side of the multichip structure 100 as shown in FIG. 1H). As shown in the multichip structure 600 of FIG. 6A, a substrate 602 is provided. As an example, the substrate 602 (or carrier wafer) can be a traditional organic substrate as known in the art, or any other suitable material(s). In certain embodiments, an adhesive layer 604 is provided on the substrate 602. The adhesive layer 604 may be comprised on any suitable material(s) and allows for the different chips 606 to be mounted to the substrate 602. Two different and physically separate chips 606 are mounted on the substrate 602 with some distance therebetween. The chips 606 may be of the same type or different types (e.g., a first die may be a memory die and a second die may be a logic die). In certain examples, the chips 606 are separated from each other by about 10 μm or more to create a space (or a trench 690) therebetween. In certain examples, the chips 606 are reconstituted and thinned chips. As shown in FIG. 6A, through-chip vias 630 are formed in each of the different chips 606. The through-chip vias 630 may comprise one or more suitable conductive materials (e.g., copper).

Referring now to FIG. 6B, this figure shows a schematic cross-sectional diagram for the multichip structure 600 of FIG. 6A at a subsequent stage of the fabrication process, in accordance with embodiments. As shown in FIG. 6B, a dielectric layer 607 is deposited over and between the chips 606. The dielectric layer 607 may be, for example, an oxide layer. In one example, the dielectric layer 607 comprises one or more of the following; SiO₂, SiN, SiCN, a polymer, an epoxy, or a suitable organic material. In an example, one or more organic oxide materials are used for the dielectric layer 607 that allow for low temperature (e.g., 175° C.) deposition. In certain examples, a height (or thickness) of the dielectric layer 607 above the upper surfaces of the chips 606 may be from 10-60 μm. This thickness of the dielectric layer 607 allows for conductor lines or metal traces (discussed in further detail below) to be formed in the dielectric layer 607 to connect the chips 606. In certain examples, the dielectric layer 607 is initially deposited over the entire surfaced of the multichip structure 600.

Referring now to FIG. 6C, this figure shows a schematic cross-sectional diagram for the multichip structure 600 of FIG. 6B at a subsequent stage of the fabrication process, in accordance with embodiments. As shown in FIG. 6C, through-dielectric vias 608 are formed in the dielectric layer 607 with any suitable combination of patterning, material deposition and material removal steps. The through-dielectric vias 608 (or conductor lines) may be comprised of any suitable conductive material (e.g., copper). As shown in FIG. 6C, the through-dielectric vias 608 and through-chip vias 630 form electrical connections (e.g., BEOL wirings) between the two different chips 606.

Referring now to FIG. 6D, this figure shows a schematic cross-sectional diagram for the multichip structure 600 of FIG. 6C at a subsequent stage of the fabrication process, in accordance with embodiments. As shown in FIG. 6D, the substrate 602 and the adhesive layer 604 are removed. Then, metal contacts 611 (or pads, or under bump metal layers) are formed on the dielectric layer 607 to make contact with the through-dielectric vias 632. The metal contacts 611 are configured to accept solder bumps (discussed in detail below) at a later stage of the manufacturing process. In certain embodiments, additional metal contacts 611 are formed on the bottom of the chips 606. Then, a number of solder features 614 are formed on the metal contacts 611. In an embodiment, the solder features 614 are solder balls from a ball grid array (BGA). As shown, the solder features 614 may permit the microchip structure 600 to be mounted and electrically coupled to, for example, an underlying printed circuit board (PCB) or other components. In certain embodiments, the bottoms of the solder features 614 are generally coplanar. In certain embodiments, the metal contacts 611 and the solder features 614 that are connected to the through-dielectric vias 632 may be omitted from the area of the dielectric layer 607 that is between the chips 606. It should be appreciated that the number, size and arrangement of the different solder features may be different than that shown in FIG. 6D and may be any suitable combination depending on the application.

Referring now to FIG. 6E, this figure shows a schematic cross-sectional diagram for the multichip structure 600 of FIG. 6D at a subsequent stage of the fabrication process, in accordance with embodiments. As shown in FIG. 6E, a lid 622 is attached to the laminate substrate 620 and covers the multichip structure 600. The lid 622 may be a cover that has a hollow portion 664 to house the multichip structure 600 and also contact the laminate substrate 620. The vertical wall portions of the lid 622 may be formed to have a height that generally corresponds to the height of the multichip structure 600 in order to create a hermetic seal for the multichip structure 600. Thus, as shown in FIGS. 6A-6E, a simplified assembly process is achieved as compared to, for example, a silicon bridge on packaging substrate. Similar to the embodiments described above with respect to FIGS. 1A-1H, this may allow for a higher yield than related package assembly techniques, and it is not necessary to utilize a silicon bridge, which may allow for the inter-die connection pathways to have shorter travel distances, a lower energy requirement (e.g., pJ/bit) for the communication, a higher latency, and/or a higher bandwidth than related structures. In certain embodiments, dummy heat extraction vias 636 may be formed through the dielectric layer 607 to aid in heat transfer/extraction. The heat extraction vias 636 may provide a structure between the chips 606 and the lid 622 that allows for efficient heat transfer from the chips 606 to the lid 622.

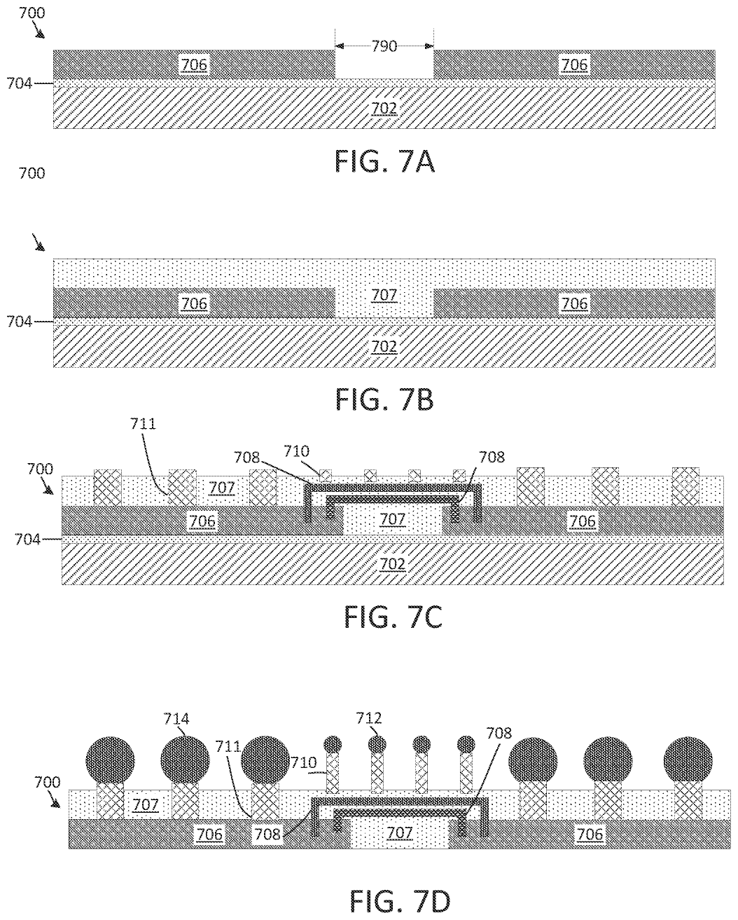

Referring now to FIG. 7A, this figure shows a schematic cross-sectional diagram for a multichip structure 700 for chip-to-chip connections at an intermediate stage of the manufacturing process, in accordance with embodiments. As shown the multichip structure 700 of FIG. 7A, a substrate 702 is provided. The substrate 702 (or carrier wafer) can be a traditional organic substrate as known in the art, or any other suitable material(s). In certain embodiments, an adhesive layer 704 is provided on the substrate 702. The adhesive layer 704 may be comprised on any suitable material(s) and allows for the different chips 706 to be mounted to the substrate 702. Two physically separate chips 706 are mounted on the substrate 702 with some distance therebetween, thus forming a trench 790 between the chips. The chips 706 may be of the same type or different types (e.g., a first die may be a memory die and a second die may be a logic die). In certain examples, the chips 706 are separated from each other by about 10 μm or more to create a space (or a trench 190) therebetween. In certain examples, the chips 706 are reconstituted and thinned chips.

Referring now to FIG. 7B, this figure shows a schematic cross-sectional diagram for the multichip structure 700 of FIG. 7A at a subsequent stage of the fabrication process, in accordance with embodiments. As shown in FIG. 7B, a dielectric layer 707 is deposited over and between the chips 706. The dielectric layer 707 may be, for example, an oxide layer. In one example, the dielectric layer 707 comprises one or more of the following; SiO₂, SiN, SiCN, a polymer, an epoxy, or a suitable organic material. In an example, one or more organic oxide materials are used for the dielectric layer 707 that allow for low temperature (e.g., 175° C.) deposition. In certain examples, a height (or thickness) of the dielectric layer 707 above the upper surfaces of the chips 706 may be from 10-60 μm. This thickness of the dielectric layer 707 allows for conductor lines (discussed in further detail below) to be formed in the dielectric layer 707 to connect the chips 706. In certain examples, the dielectric layer 707 is initially deposited over the entire surfaced of the multichip structure 700. In an example, a ratio of the height (or thickness) of the dielectric layer 707 above the surface of the adhesive layer 704 to the distance between the chips 706 is about 1:1. However, it should be appreciated that other suitable ratios of the height to separation distance may be used.

Referring now to FIG. 7C, this figure shows a schematic cross-sectional diagram for the multichip structure 700 of FIG. 7B at a subsequent stage of the fabrication process, in accordance with embodiments. As shown in FIG. 7C, through-dielectric vias 708 are formed in the dielectric layer 707 with any suitable combination of patterning, material deposition and material removal steps. In certain embodiments, the through-dielectric vias 708 may extend partially into the chips 706. The through-dielectric vias 708 (or conductor lines) may be comprised of any suitable conductive material (e.g., copper). Then, metal contacts 710 (or pads, or under bump metal layers) are formed on the dielectric layer 707 on or above the through-dielectric vias 708. In certain embodiments, second metal contacts 711 are formed above the chips 706 through the dielectric layer 707. The metal contacts 710 and second metal contacts 711 are configured to accept solder bumps (discussed in detail below) at a later stage of the manufacturing process. As shown in FIG. 7C, the through-dielectric vias 708 and the dielectric layer 707 form electrical connections (e.g., BEOL wirings) between the two different chips 706. Although not shown in FIG. 7C, a dicing operation may be performed on the multichip structure 700 to separate it from other multichip structures (not shown).

Referring now to FIG. 7D, this figure shows a schematic cross-sectional diagram for the multichip structure 100 of FIG. 7C at a subsequent stage of the fabrication process, in accordance with embodiments. As shown in FIG. 7D, the substrate 702 and the adhesive layer 704 are removed. Then, first solder features 712 and second solder features 714 are formed on the first metal contacts 710 and second metal contacts 711, respectively. The first solder features 712 may have a smaller size than the second solder features 714. In this example, the height of the first solder features 712 may be increased with a solder cap (not shown) to increase the height to be same as the second solder features 714. In one example, this increase in height is achieved by plating the first metal contacts 710 and the second metal contacts 711 separately, for different heights, using selective resist deposition and stripping. In other embodiments, the first solder features 712 are the same size as the second solder features 714 so that the tops of the solder features are generally at the same height. It should be appreciated that a reflow operation may be performed on the solder features 712 and the second solder features 714. It should also be appreciated that a laminate substrate and a lid may be attached to the multichip structure 700, similar to other embodiments described herein.

Reference in the specification to “one embodiment” or “an embodiment,” as well as other variations thereof, means that a particular feature, structure, characteristic, and so forth described in connection with the embodiment is included in at least one embodiment. Thus, the appearances of the phrase “in one embodiment” or “in an embodiment,” as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between’ two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A microelectronic package comprising:
a substrate;
a first die and a second die attached to the substrate; and
a dielectric structure including at least one electrical wiring electrically connecting the first die to the second die.

2. The microelectronic package of claim 1, wherein the dielectric structure comprises at least one dielectric material selected from the group consisting of SiO₂, SiN, SiCN, a polymer, an epoxy, and an organic material.

3. The microelectronic package of claim 1, wherein the electrical wiring includes at least one through-dielectric via that comprises Cu.

4. The microelectronic package of claim 1, wherein the dielectric structure connecting the first die and the second die is between the first and second dies and the substrate.

5. The microelectronic package of claim 1, wherein the first die and the second die are between the electrical wiring and the substrate.

6. The microelectronic package of claim 1, further comprising a lid attached to the substrate, the lid covering the dielectric structure, the first die and the second die.

7. The microelectronic package of claim 6, wherein the dielectric structure is positioned between the first and second dies and the lid.

8. The microelectronic package of claim 1, wherein at least one of the first die and the second die includes a through-chip via that connects to the at least one electrical wiring.

9. The microelectronic package of claim 1, wherein the first die and the second die are separated by at least 10 μm.

10. The microelectronic package of claim 9, wherein a separation area between the first die and the second die is filled with a dielectric material.

11. A method of manufacturing a microelectronic package, the method comprising:
attaching a first die and a second die to a substrate; and
forming a dielectric structure including at least one electrical wiring that electrically connects the first die to the second die.

12. The method of claim 11, wherein the dielectric structure comprises at least one selected from the group consisting of SiO₂, SiN, SiCN, a polymer, an epoxy, and an organic material.

13. The method of claim 11, wherein the at least one electrical wiring includes a through-dielectric via that comprises Cu.

14. The method of claim 11, further comprising forming the dielectric structure between the first and second dies and the substrate.

15. The method of claim 11, further comprising forming the first die and the second die between the through-dielectric vias and the substrate.

16. The method of claim 11, further comprising attaching a lid to the substrate, the lid covering the dielectric structure, the first die and the second die.

17. The method of claim 16, further comprising forming the dielectric structure between the first and second dies and the lid.

18. The method of claim 11, further comprising forming a through-chip via in at least one of the first die and the second die, the through-chip via connected to the at least one electrical wiring.

19. The method of claim 11, wherein the first die and the second die are separated by at least 10 μm.

20. The method of claim 19, further comprising filling a separation area between the first die and the second die with a dielectric material.
